(19) United States
(12) Patent Application Publication
(10) Pub. No.: US 2013/0255741 A1
(43) Pub. Date: Oct. 3, 2013

(54) STRUCTURE AND METHOD FOR COUPLING HEAT TO AN EMBEDDED THERMOELECTRIC DEVICE

(71) Applicant: TEXAS INSTRUMENTS INCORPORATED, Dallas, TX (US)

(72) Inventors: Henry L. Edwards, Garland, TX (US); Richard B. Irwin, Richardson, TX (US); Tathagata Chatterjee, Allen, TX (US)

(21) Appl. No.: 13/798,878

(22) Filed: Mar. 13, 2013

Related U.S. Application Data
(63) Continuation-in-part of application No. 12/790,688, filed on May 28, 2010.
Application No. 12/790,688 is a continuation-in-part of application No. 12/201,679, filed on Aug. 29, 2008.
(60) Provisional application No. 61/182,052, filed on May 28, 2009.
(60) Provisional application No. 61/182,055, filed on May 28, 2009.
(60) Provisional application No. 60/968,805, filed on Aug. 29, 2007.

(51) Int. Cl. H01L 35/30; H01L 35/34

(52) U.S. Cl. CPC H01L 35/30; H01L 35/34
USPC 136/207; 438/54; 136/201

(57) ABSTRACT

An integrated circuit with an embedded heat exchanger for coupling heat to an embedded thermoelectric device from a thermal source that is electrically isolated from a thermoelectric device. A method for forming an integrated circuit with an embedded heat exchanger.

This application is a continuation-in-part of application No. 12/790,688 filed May 28, 2010, which application No. 12/790,688 is a continuation-in-part of application No. 12/201,679 filed Aug. 29, 2008 and also claims priority from and the benefit of Provisional Application Nos. 61/182,052 filed May 28, 2009 and 61/182,055 filed May 28, 2009; which application No. 12/201,679 claims priority from and the benefit of application No. 60/968,805 filed Aug. 29, 2007; the entireties of all of which are incorporated herein by reference.

### BACKGROUND

This relates to the field of integrated circuits. More particularly, this relates to a thermoelectric device in an integrated circuit.

Thermoelectric devices embedded in integrated circuits are well known. Generally heat flows vertically from the top of the integrated circuit through the thermoelectric device to the substrate, whereas electrical current flows through the thermoelectric device horizontally. It is desirable to maintain a constant temperature gradient across the thermoelectric device to maintain a constant output. Thermal coupling between levels may cause heat to flow toward or away from various portions of the thermoelectric device making this difficult. In other instances, thermal coupling between layers may be desirable to guide heat from a heat source to the thermoelectric device.

The interconnect layers in an integrated circuits are good conductors of heat and are also good conductors of electricity. Since heat in an embedded thermoelectric device generally flows vertically through interconnect layers and electrical current generally flows horizontally through interconnect layers, isolation of the thermal path from the electrical path may be desirable.

### SUMMARY

An integrated circuit with an embedded heat exchanger for coupling heat to an embedded thermoelectric device from a thermal source that is electrically isolated from the thermoelectric device. Structures and methods for improving the coupling of heat to an embedded thermoelectric device and isolating the thermal path from the electrical path.

### BRIEF DESCRIPTION OF THE DRAWINGS

FIG. 1 is a cross-sectional view of a thermoelectric device.

FIG. 2 is a cross-sectional view of an integrated circuit with embedded heat exchanger and embedded thermoelectric device according to principles of the invention.

FIG. 3 is a cross-sectional view of a portion of an embedded heat exchanger according to principles of the invention.

FIG. 4 is a pattern of an interconnect layer for an embedded heat exchanger according to principles of the invention.

FIGS. 5 and 6 are patterns of via levels for an embedded heat exchanger according to principles of the invention.

FIG. 7 is a cross-sectional view of an integrated circuit with embedded heat exchanger and embedded thermoelectric device according to principles of the invention

FIGS. 8 and 9 are patterns of interconnect layers for an embedded heat exchanger according to principles of the invention.

FIGS. 10, 11 and 12 are patterns of via and interconnect layers for an embedded heat exchanger according to principles of the invention.

FIGS. 13 and 14 are cross-sectional views of an embedded heat exchanger according to principles of the invention.

FIG. 15 is an illustration of a cross section at location 172 in FIG. 13.

### DETAILED DESCRIPTION OF EXAMPLE EMBODIMENTS

Embedded thermoelectric devices are described in application No. 12/201,679, filed Aug. 29, 2008, incorporated herein by reference. As metal is an efficient conductor for thermal energy as well as for electricity, integrated circuit interconnect materials may be utilized both for conducting thermal energy to and from an embedded thermoelectric device as well as for conducting electrical signals to and from the embedded thermoelectric device. Since thermal energy typically flows vertically through an embedded thermoelectric device and electrical energy typically flows horizontally through and embedded thermoelectric device, isolation of the thermal path from the electrical path may be advantageous while still providing strong thermal coupling to the embedded thermoelectric device.

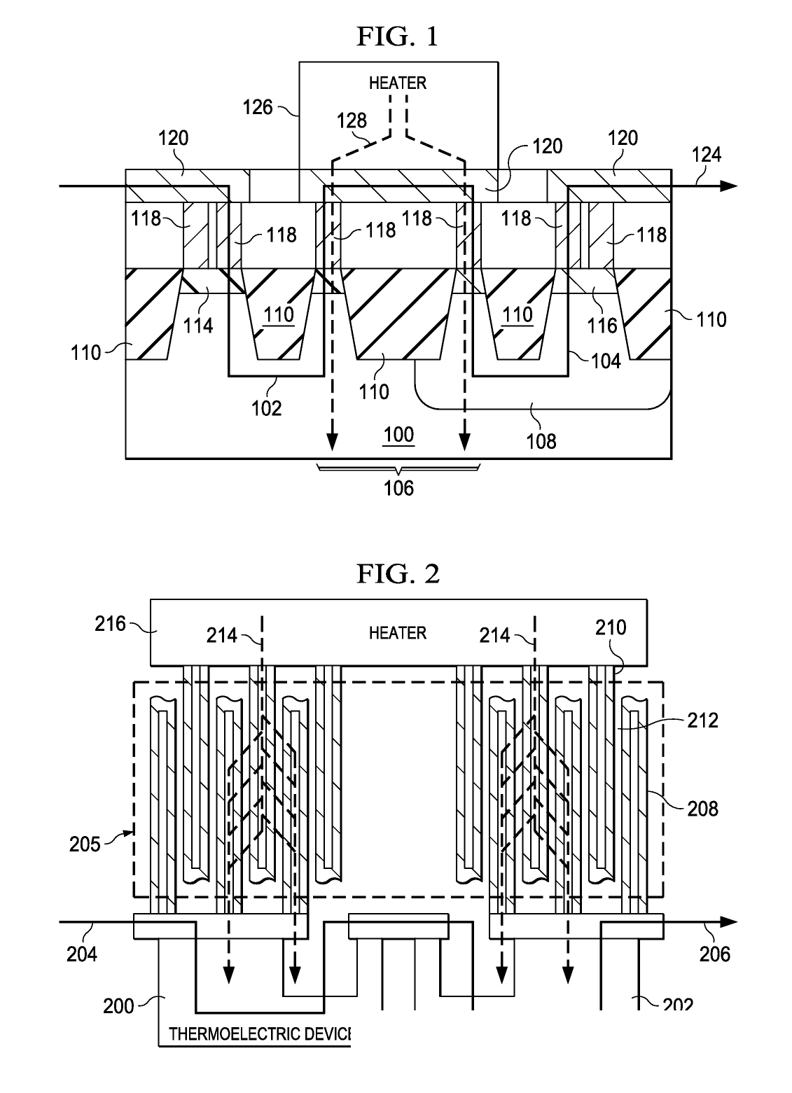

FIG. 1 illustrates the thermal and electrical paths through an example integrated circuit with an embedded thermoelectric device. Thermoelectric device, 106, is a thermocouple composed of two thermopiles, 102 and 104. P-type thermopile, 102, is formed in the p-type substrate, 100, and n-type thermopile, 104, is formed in nwell, 108. Thermal energy from heater, 126, flows vertically through thermoelectric device, 106, as indicated by dashed arrows, 128. Electrical current flows through thermoelectric device, 106, as shown by solid arrow, 124. The electrical current flows through interconnect, 120, contacts 118, pwell contact diffusion, 114, thermocouple, 106, and then out through nwell contact, 116. The thermopiles, 102 and 104, are electrically isolated from each other and from pwell and nwell contacts, 114 and 116, with shallow trench isolation, 110. To enhance operation of the thermoelectric device the substrate, 100, may be cooled. It is also possible to operate the thermoelectric device, 106, by heating the substrate, 100, and cooling the topside of the thermoelectric device, 106.

An integrated circuit with an embedded thermoelectric device may be formed with the thermal path isolated from the electrical path using an embedded heat exchanger, 205, as shown in an embodiment illustrated in FIGS. 2, 3, 4, 5 and 6. The heat exchanger, 205, maybe constructed within the interconnect layers of the integrated circuit with no additional processing steps and no additional manufacturing cost.

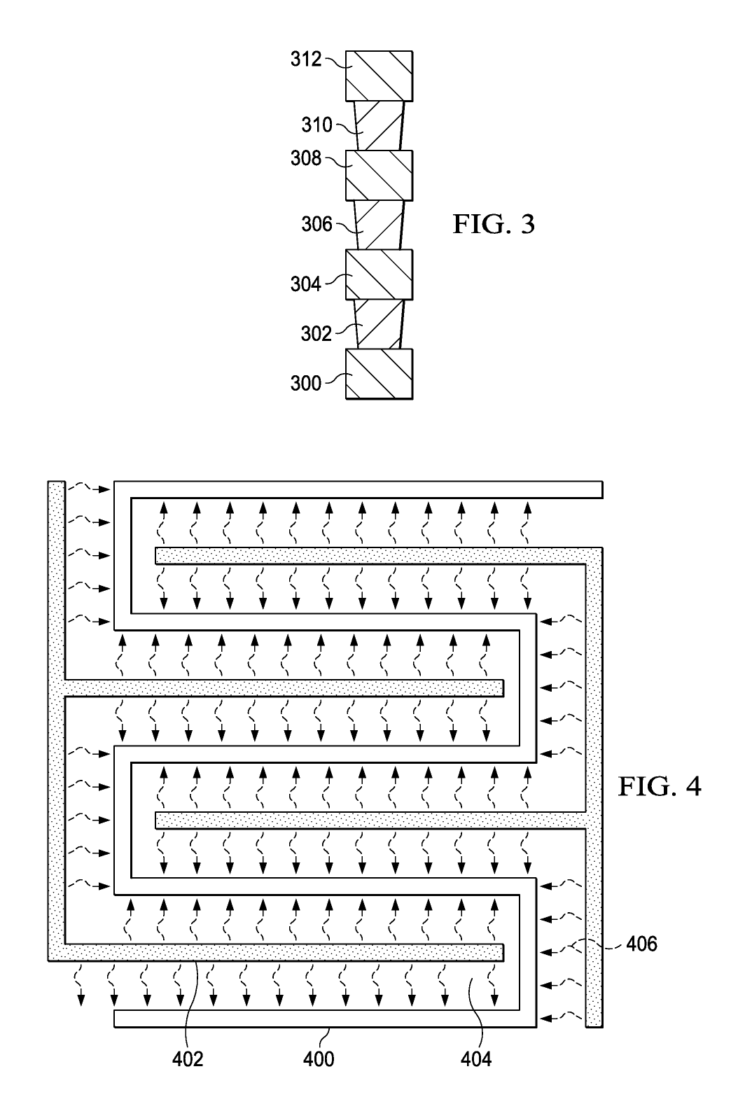

As shown in FIG. 2, inside the embedded heat exchanger, 205, metal heat emission fins, 210, are interdigitated with heat collection fins, 208. Heat collection fins, 208, are coupled to thermoelectric device A, 200, and thermoelectric device B, 202. Dielectric, 212, electrically isolates the heat emission fins, 210, from the heat collection fins, 208. Heat flows along thermal paths illustrated by vertical dashed lines, 214, from the heater, 216; through the heat emission fins, 210; through the dielectric, 212; through the heat collection fins, 208; and into the thermoelectric devices, 200 and 202. The electrical path is indicated by solid arrow, 206. A large surface area may be formed between the heat emission fins, 210, and the heat collection fins, 208 to improve heat transfer from the heater, 216, to the thermoelectric devices, 200 and 202. As is illustrated in FIG. 3, several layers of interconnect such as, 300, 304, 308, and 312, may be connected together with vias such as, 302, 306, and 310, to form heat emission fins, 210, and heat collection fins, 208 with a large surface area for heat transfer.

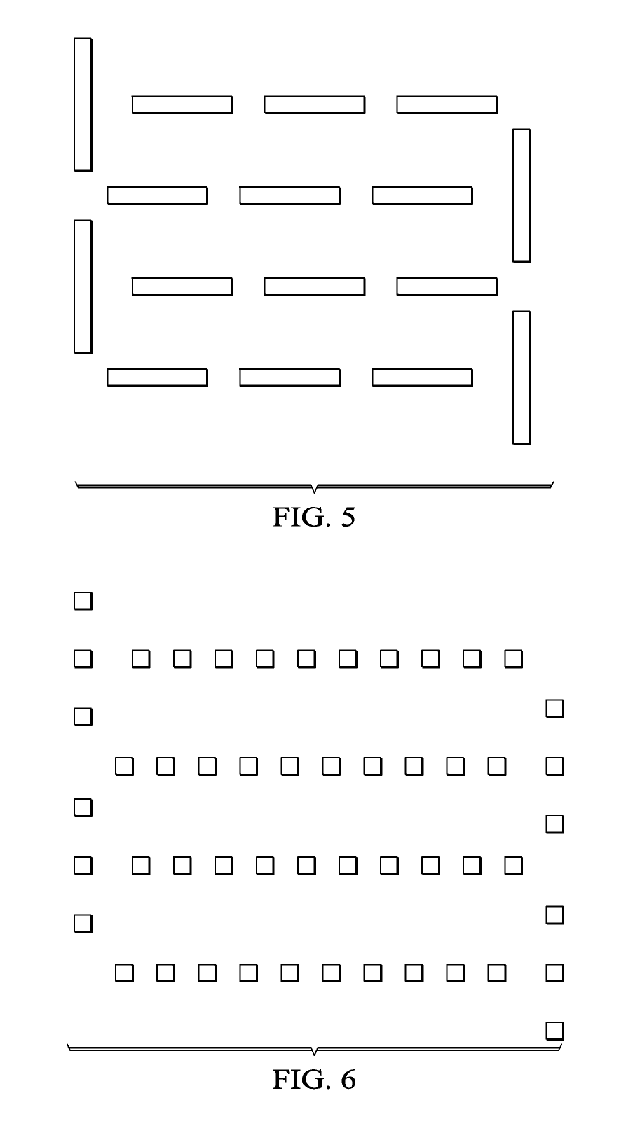

An example fin structure according to this embodiment is illustrated in FIG. 4 showing a top down view of heat emission fins, 402, and heat collection fins, 400. Thermal energy is transferred from the heat emission fins, 402, across dielectric filled region, 404, to the heat collection fins, 400, as indicated by the arrows, 406. Fins, 400 and 402, may be composed of several layers of interconnect stacked one on top of another as shown in the cross section in FIG. 3 and may be connected together using via slots such as are shown in FIG. 5, or using vias as shown in FIG. 6. The via slots in FIG. 5, may be more efficient at conducting thermal energy between the interconnect layers.

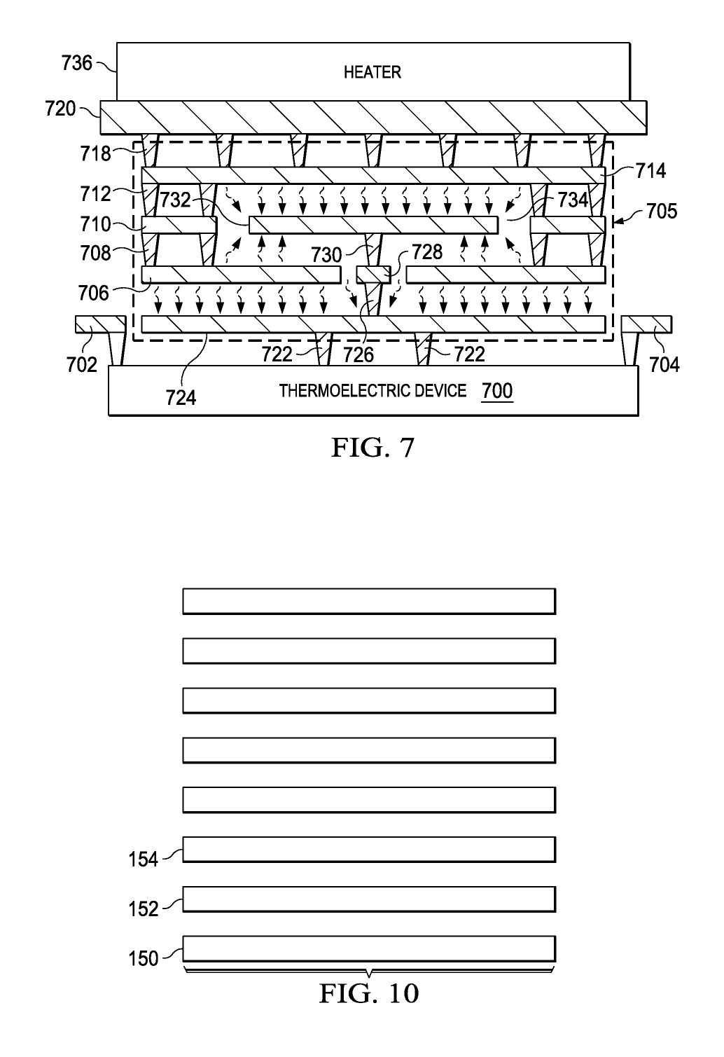

Another example embodiment that may provide improved thermal coupling is illustrated in FIGS. 7, 8 and 9. A cross section of an embedded thermoelectric device,700, with an embedded heat exchanger, 705, is shown in FIG. 7. The electrical signal flows from input, 702, through thermoelectric device, 700, to output, 704. Thermal energy flows mostly in the vertical dimension as shown by the broken arrows from heater, 736, down through the heat exchanger, 705, to the thermoelectric device, 700. The heater, 736, may be an external thermal energy source coupled to an upper layer of interconnect, 720, as shown in FIG. 4 or it may be an embedded resistance heater formed in one or more of the interconnect levels. If the thermal energy source is an embedded resistance heater, the embedded resistance heater may also function as the heat emission fin or a portion of the heat emission fin.

The heat emission fins in this embodiment may be composed of vias, 718, 712, and 708, which conduct thermal energy between the various interconnect layers 720, 714, 710, and 706, of the heat emission fin. The heat collection fin which is coupled to thermocouple device, 700, may be composed of vias, 726, and 730, which conduct thermal energy between the various interconnect levels, 724, 728, and 732 of the heat collection fin. Contacts, 722, may couple the heat collection fin to the thermoelectric device, 700. Dielectric fills the spaces, 734, electrically isolating the heat emission fin from the heat collection fin.

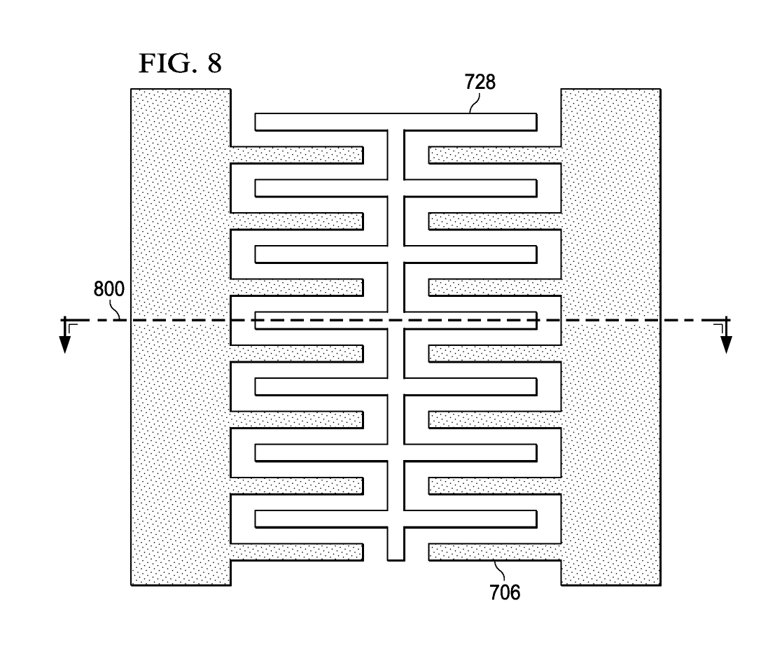

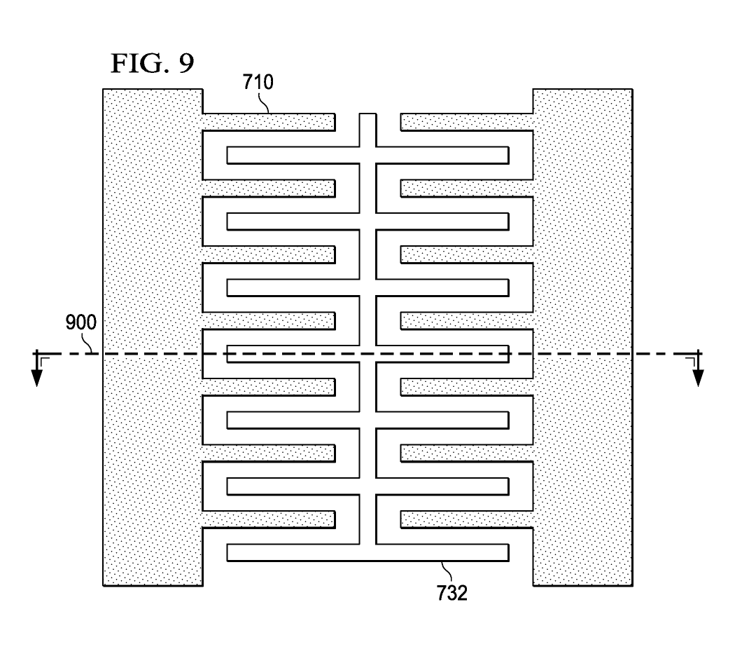

A pattern which illustrates the layout for the second level of interconnect containing heat emission and collection structures, 706 and 728, is shown in FIG. 8 and a pattern which illustrates the layout for the third level of interconnect containing heat emission and collection structures, 710 and 732, is shown in FIG. 9. The cross-sectional view in FIG. 7 is taken along the dashed line, 800, for the pattern in FIG. 8 and along the dashed line, 900, in FIG. 9. As is evident in FIGS. 8 and 9 the heat emission fins, 706 and 710, are interdigitated with the heat collection fins, 728 and 732, in the horizontal dimension providing more horizontal surface area between the heat emission fins and heat collection fins for thermal energy exchange. In addition, as shown in FIG. 7, heat collection finger, 732, in FIG. 9 overlies heat emission finger, 706, in FIG. 8 providing additional vertical surface area between the heat emission fins and the heat collection fins for additional vertical thermal energy exchange. In this example embodiment heat emission fins and heat collection fins are interdigitated in both the horizontal and the vertical dimension providing thermal coupling in both the horizontal and vertical dimensions while still providing electrical isolation.

The dielectric materials used for isolation in the interconnect levels may cause an anisotropy in thermal conductivity in the integrated circuit. For example, the low-K dielectrics have very poor thermal conductivity whereas etch stop and chemical mechanical polish stop layers such as SiN, SiC, and SiCN may be significantly more thermally conductive than low-K. Since the layers are deposited horizontally, horizontal thermal energy flow may be significantly greater than the vertical heat flow. In this case structures the vertical area between the heat emission fins and the heat collection fins may be maximized.

Another example embodiment thermal coupling structure is shown in FIGS. 10, 11 and 12. The metal interconnect layer, 150, shown in FIG. 10 may consist of interdigitated heat emission, 152, and heat collection, 154, fingers. The heat collection fingers, 154, may be connected to an underlying thermoelectric device.

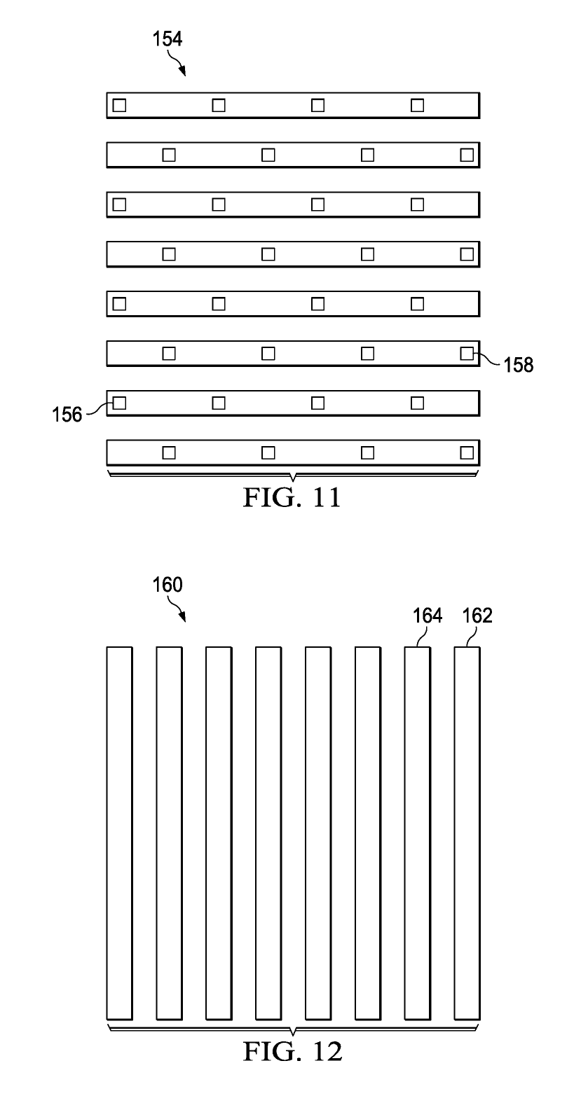

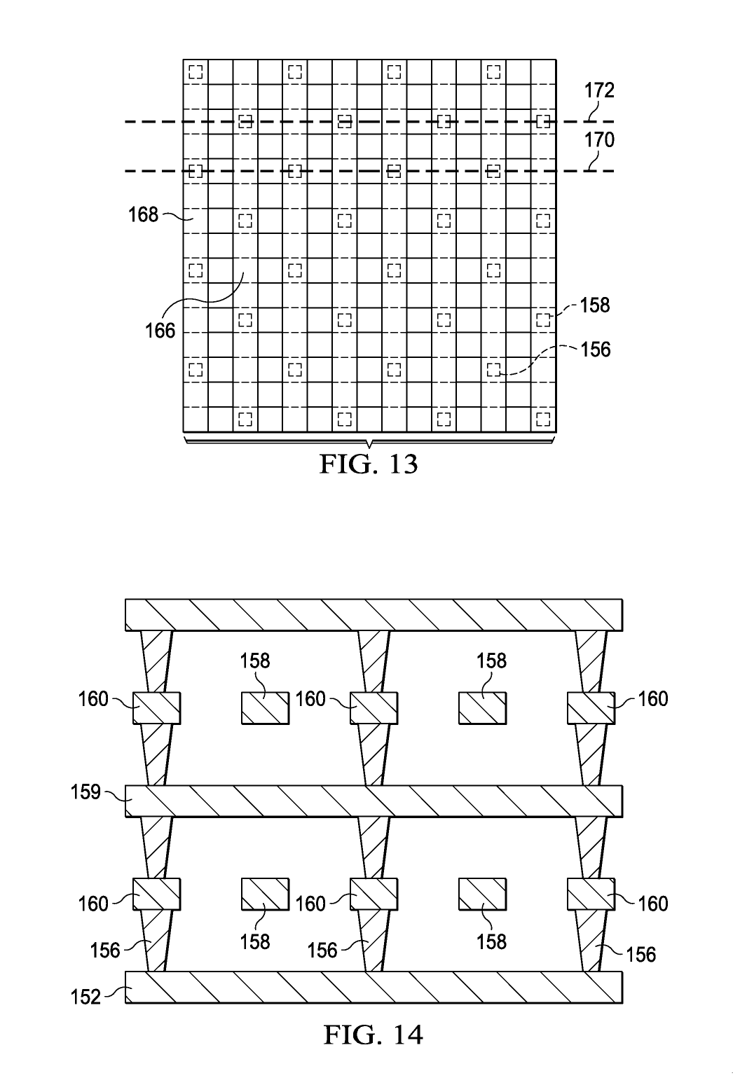

FIG. 11 shows the placement of via layer, 154, over interconnect layer, 150. As shown in FIG. 13 via, 156, connects heat emission finger 156 in the underlying interconnect layer, 150, to heat emission finger, 164, in the overlying interconnect layer, 160 (FIG. 12). Also as shown in FIG. 13 via, 158, connects heat collection finger, 162, in overlying interconnect layer, 160, to heat collection finger, 154, in underlying interconnect layer, 150. In addition to the horizontal transfer of heat between the interdigitated fingers in interconnect layer 150 and in interconnect layer 160, heat may be transferred vertically at the heat emission finger and heat collection finger crossing points, 166 and 168, in FIG. 13.

Although the heat emission and heat collection fingers are shown to be equal width and space the widths and spaces may be adjusted as needed for efficient thermal coupling. For example, wider metal leads facilitate vertical thermal coupling at the crossing points and may enable the placement of enlongated vias, whereas narrower metal leads enable the placement of more interdigitated fingers per unit area which facilitates horizontal thermal coupling.

FIG. 14 is an illustration of a cross section at location 170 in FIG. 13. Heat collection finger, 158, is surrounded by heat emission finger, 152; via, 156; and heat emission finger, 160, and overlying heat emission finger 159. FIG. 14 also illustrates that additional levels of interconnect may be added to increase the area between heat emission and heat collection surfaces for additional thermal coupling.

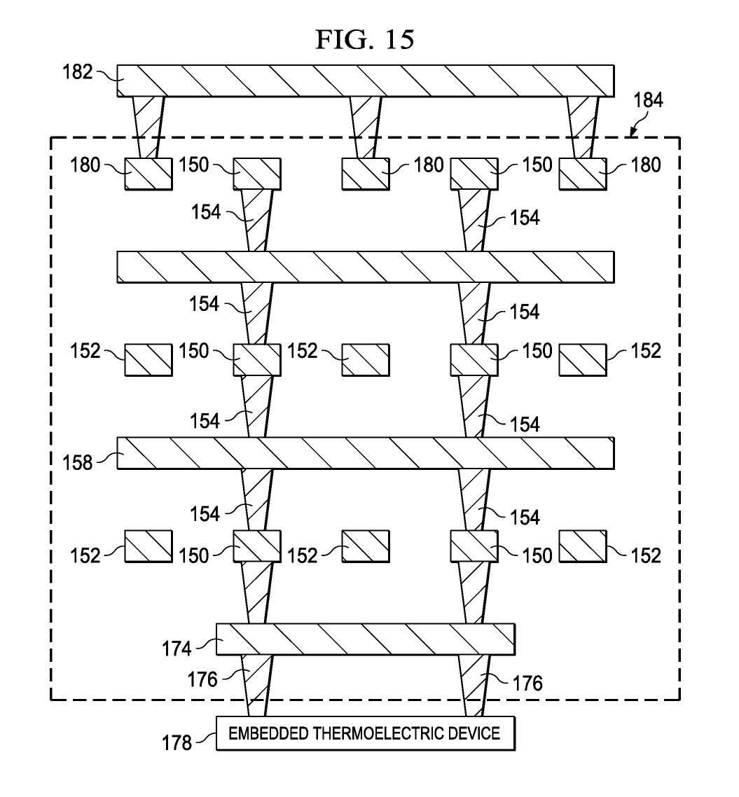

FIG. 15 is an illustration of a cross section at location 172 in FIG. 13. Heat emission finger, 152, is surrounded by heat collection fingers, 150; vias, 154, heat collection finger, 158; and heat collection finger, 174. FIG. 15 also illustrates that more levels of interconnect may be added to increase the area between heat emission and heat collection surfaces for additional thermal coupling. The heat collection portion of the heat exchanger enclosed in dotted line box, 184, may be coupled to an underlying embedded thermoelectric device, 178, with contacts, 176; and the heat emission portion of the heat exchanger, 184, may be coupled to an overlying metal pad, 182. Metal pad, 182, may be coupled to an external heat source or may be an embedded metal resistance heater that supplies thermal energy to the heat emission structure.

The structure in this embodiment shows the heat source to be above the integrated circuit with embedded thermoelectric device, 178, but the device could also function with a heat source coupled to the embedded thermoelectric device, 178, on the bottom and a heat sink coupled to the top metal pad, 182. In this instance, the roles of the heat emission structure and the heat collection structures would be reversed.

Those skilled in the art to which this invention relates will appreciate that many other embodiments and variations are possible within the scope of the claimed invention.

What is claimed is:

1. An integrated circuit, comprising:
an embedded thermoelectric device; and
an embedded heat exchange structure;
wherein a heat collection structure portion of the embedded heat exchange structure is electrically isolated from a heat emission structure portion of the embedded heat exchange structure; and
wherein the heat collection structure is coupled to an embedded thermoelectric device.

2. The integrated circuit of claim 1, wherein the embedded heat exchange structure further comprises a first interconnect layer with heat collection interconnect and heat emission interconnect.

3. The integrated circuit of claim 2, wherein the heat collection interconnect and the heat emission interconnect are interdigitated fingers separated by a dielectric.

4. The integrated circuit of claim 1, wherein the embedded heat exchange structure comprises at least a second interconnect layer with heat collection fingers and heat emission fingers coupled to the first interconnect layer with vias.

5. The integrated circuit of claim 4, wherein the heat collection fingers and the heat emission fingers of the second interconnect layer are parallel to the heat collection fingers and the heat emission fingers of the first interconnect layer.

6. The integrated circuit of claim 4, wherein the heat collection fingers and the heat emission fingers of the second interconnect layer are perpendicular to the heat collection fingers and the heat emission fingers of the first interconnect layer.

7. The integrated circuit of claim 6, wherein a width of the heat collection fingers and a width of the heat emission fingers is larger than a space between the heat collection fingers and the heat emission fingers.

8. The integrated circuit of claim 4, wherein the vias are rectangular vias.

9. The integrated circuit of claim 1, wherein the heat emission structure is an embedded resistor.

10. The integrated circuit of claim 1, wherein the heat emission structure is coupled to a thermal source external to the integrated circuit.

11. The integrated circuit of claim 10, wherein the thermal source is located over the integrated circuit and over the embedded thermoelectric device.

12. The integrated circuit of claim 10, wherein the thermal source is located under the integrated circuit and under the embedded thermoelectric device.

13. The integrated circuit of claim 4, wherein the heat collection finger in the second interconnect layer at least partially overlies the heat emission finger in the first interconnect layer, and wherein the heat emission finger in the second interconnect layer at least partially overlies the heat collection finger in the first interconnect layer.

14. An integrated circuit, comprising:
an embedded thermoelectric device; and
an embedded heat exchange structure;
wherein the heat exchange structure is formed with more than one heat emission finger and more than one heat collection finger in at least one interconnect level;
wherein the heat emission fingers and the heat collection fingers are interdigitated and are electrically isolated; and
wherein the heat emission fingers are coupled to a heat source and the heat collection fingers are coupled to the thermoelectric device.

15. The integrated circuit of claim 14, wherein the embedded heat exchange structure is formed with at least two interconnect levels, wherein the heat collection fingers in a first interconnect level are parallel to and directly underlie the heat collection fingers in a second interconnect level, and wherein the heat emission fingers in the first interconnect level are parallel to and directly underlie the heat emission fingers in the second interconnect level.

16. The integrated circuit of claim 14, wherein the embedded heat exchange structure is formed with at least two interconnect levels, wherein the heat collection fingers in a first interconnect level are perpendicular to and underlie the heat collection fingers in a second interconnect level, and wherein the heat emission fingers in the first interconnect level are perpendicular to and underlie the heat emission fingers in the second interconnect level.

17. The integrated circuit of claim 14 wherein the embedded heat exchange structure is formed with at least two interconnect levels, wherein the heat collection fingers in a first interconnect level are parallel to and partially directly underlie the heat emission fingers in a second interconnect level, and wherein the heat emission fingers in the first interconnect level are parallel to and partially directly underlie the heat collection fingers in the second interconnect level.

18. The integrated circuit of claim 14, wherein the embedded heat exchange structure is formed with at least two interconnect levels, wherein the heat emission fingers in a first interconnect level are coupled to the heat emission fingers in a second interconnect level with rectangular vias, and wherein the heat collection fingers in the first interconnect level are coupled to the heat collection fingers in the second interconnect level with rectangular vias.

19. The integrated circuit of claim 14, wherein at least one of the heat emission fingers is a resistance heater.

20. The method of forming an embedded heat exchanger in an integrated circuit containing a thermoelectric device comprising:
forming at least one interconnect layer with electrical leads, a heat emission structure, and a heat collection structure, wherein the heat emission structure and the heat collection structure form the embedded heat exchanger;
forming contacts or vias to couple the heat collection structure to the embedded thermoelectric device; and
forming vias to couple the heat emission structure to a thermal source.

21. The method of claim 20 further comprising:
forming an embedded resistance heater where the embedded resistance heater is the thermal source and where the embedded resistance heater forms a portion of the heat emission structure.
